(19) United States
(12) Patent Application Publication
(10) Pub. No.: US 2006/0252243 A1
(43) Pub. Date: Nov. 9, 2006

(54) Epitaxial film deposition system and epitaxial film formation method

(75) Inventors: Daisuke Kishimoto, Fukushima-ken (JP); Takeshi Tawara, Matsumoto-shi (JP); Shunsuke Izumi, Yokosuka-shi (JP)

Correspondence Address: KANESAKA BERNER AND PARTNERS LLP, SUITE 300, 1700 DIAGONAL RD, ALEXANDRIA, VA, 22314-2848, US

(73) Assignee: FUJI ELECTRIC HOLDINGS CO., LTD., Kawasaki-shi (JP)

(21) Appl. No.: 11/398,659

(22) Filed: Apr. 6, 2006

(30) Foreign Application Priority Data
Apr. 20, 2005 (JP) 2005-122107

(51) Int. Cl. H01L 21/44; H01L 21/76

(52) U.S. Cl. 438/607; 438/413

(57) ABSTRACT

An epitaxial film deposition system includes a reactor, a susceptor, a wafer heating unit, a reactant gas supply orifice, and an aperture for venting the reactant gas. The reactant gas is supplied to a reactor region between the susceptor and a graphite plate so as to circulate in layered flow in a direction along the reactor inner wall in the planar direction of a mounted SiC wafer. The temperature of the wafer is controlled by a high frequency coil and halogen lamps based on temperatures detected by a pyrometer. By circulating the reactant gas over the surface of the stationary wafer, it is possible to form, under various process conditions, an SiC epitaxial film having good film quality and good uniformity of film thickness, without providing any wafer rotation mechanism.

### BACKGROUND OF THE INVENTION AND RELATED ART STATEMENT

The present invention relates to an epitaxial film deposition system and an epitaxial film deposition method, and in particular, relates to an epitaxial film deposition system and an epitaxial film deposition method which are used in formation of an epitaxial film of silicon carbide (SiC) or silicon (Si) or the like.

Although Si is the main material used at the moment for semiconductor devices, it is predicted that the replacement thereof by SiC will progress from now onward, in particular in the field of semiconductor devices for electric power or the like. However, when forming an SiC film by epitaxial growth during the formation of a semiconductor device, the current situation is that there is no effective unit which can reliably prevent crystal defects such as so-called micro pipes and stacking faults, such as are sometimes created during such film formation. It is strongly desirable to provide a stable unit for forming an SiC epitaxial film of which the crystal product quality is high, and which moreover is endowed with satisfactory uniformity of film thickness, and satisfactory uniformity of density of doping impurity, both within a single wafer, and also between a plurality of wafers.

In the past, various types of epitaxial film deposition systems for semiconductors have been developed, such as one in which a wafer is disposed within a tubular furnace and film formation is performed by flowing a reactant gas in one direction over it, and one in which film formation is performed while rotating the wafer within a furnace under a flow of reactant gas, and the like; and improvement thereof is also continuing. For example, in relation to an epitaxial film deposition system which is used for forming an Si epitaxial film, when such a wafer rotation mechanism has been provided, in order to avoid metallic contamination which is caused by a gas for purging of this wafer rotation mechanism also flowing onto the wafer as well during the Si epitaxial growth, for this purge gas, it has been proposed to provide a gas exhaust aperture which is different from the exhaust aperture for the reactant gas. For example, refer to Japanese Patent Laid-Open Publication No. Heisei 7-221022.

It should be understood that, in relation to a CVD (Chemical Vapor Deposition) device which performs film formation by accumulating Si or SiC, with the objective of avoiding turbulence, originating in the temperature distribution within the chamber, undesirably occurring in the flow of reactant gas when the reactant gas flows through in a single direction, a device has also been proposed in which the chamber is built with an outer tube which is closed at one end and with an inner tube which is opened at both ends, and in which the wafer is arranged at the inner wall of the inner tube and the reactant gas flows through into this from one direction, so that thereafter this reactant gas is conducted along the inner wall of the closed end of the outer tube to the exterior side of the inner tube, and is exhausted to the exterior of the device, or the like. For example, refer to Japanese Patent Laid-Open Publication 2002-252176.

However, there has been the problem that, when forming an SiC epitaxial film with such a prior art epitaxial film deposition system, it is not possible to satisfy, simultaneously and at a high level, the full width and so on of the range of process conditions, not only such as crystalline product quality, film thickness uniformity, and impurity density uniformity, but also temperature and pressure and the like.

For example, in a device of a structure which performs film formation by a wafer being disposed within a tubular furnace and, by flowing a reactant gas past this wafer in a single direction, without restriction to formation of an SiC epitaxial film and also when forming an Si epitaxial film as well, differences may occur in the film thickness uniformity and in the impurity density uniformity between upstream and downstream of the reactant gas, irrespective of whether the device is of the hot wall type or the cold wall type. This is because the reactant gas progressively crystallizes on the wafer in order from upstream, so that the composition of the reactant gas progressively changes as it passes downstream, which is undesirable, and it is a problem which theoretically cannot be avoided.

Furthermore, in epitaxial growth of a film of Si or gallium 10 arsenide (GaAs) or the like, in order to enhance its film quality and film thickness, it is typical to provide a rotation mechanism within the epitaxial film deposition system, and to perform the formation of the film while rotating it at a rotation speed of around 10 rpm to 50 rpm. However since, for epitaxial growth of SiC, its growing temperature is 1500° C. even-when low, and exceeds 2000° C. when high, accordingly there have been difficult problems with providing such a wafer rotation mechanism within the epitaxial film deposition system, with regard to its own structure.

As for the susceptor on which is mounted the SiC wafer on which the SiC epitaxial film is to be formed, although generally one made of graphite is used, if a quartz glass shaft is connected to such a graphite susceptor as a rotation shaft, this quartz glass deforms little by little along with use, and it becomes necessary to change it every few tens to few hundreds of hours of operation. On the other hand, when the rotation shaft which is connected to the susceptor is made from graphite just as is the susceptor itself, due to heat conduction, heat at high temperature is conducted through to components which are attached to the rotation shaft externally to the reactor, and there is an undesirable possibility that a gas retention mechanism such as, for example, a magnetic seal chuck, or the motor for rotation itself or the like, may be destroyed. Furthermore, if a metal which is strong in the high temperature region, such as tantalum (Ta), tungsten (W), or molybdenum (Mo), is used for the rotation shaft, then the possibility is high that metallic contamination of the SiC wafer or of the SiC epitaxial film may occur, and, even supposing that the device were to be made so as to be able to suppress the occurrence of such metallic contamination, the problem still would remain that the cost of the device would be undesirably high.

In this manner, with a prior art epitaxial film deposition system in which a wafer rotation mechanism is provided, although there has been no problem when forming an Si epitaxial film or the like, in a case such as when the susceptor attains an extremely high temperature as when forming an SiC epitaxial film or the like, it has been difficult to implement a mechanism for holding it. Due to this, even when an attempt is made to form an SiC epitaxial film, it is only possible to raise its temperature of growth to around 1500° C. to 1600° C. at most. As a result, formation of an SiC epitaxial film in the very high temperature region of 1800° C. to 2000° C. has not been performed, and it has been difficult to form an SiC epitaxial film with the qualities desired, since the range of process conditions has become narrowed.

Further objects and advantages of the invention will be apparent from the following description of the invention and the associated drawings.

### SUMMARY OF THE INVENTION

The present invention has been developed in order to address the above identified problems. An object of the invention is to provide an epitaxial film deposition system and an epitaxial film deposition method which are capable, under various process conditions, of forming various epitaxial films of which the film quality and the uniformity of the impurity density and the film thickness and so on are satisfactory.

In order to solve the above described problems, according to the present invention, there is provided an epitaxial film deposition system which performs formation of an epitaxial film. The device includes: a reactor which includes a tubular inner wall; a susceptor, provided within the reactor, and on which a wafer is mounted so that the planar direction of a surface thereof on which the epitaxial film is to be formed is oriented approximately orthogonally to the inner wall; a first heating unit which heats the wafer mounted on the susceptor; a supply orifice which supplies a reactant gas into the reactor so as to circulate in a direction along the inner wall of the reactor, the direction being approximately parallel to the surface of the wafer on which the epitaxial film is to be formed; and an exhaust aperture which vents the reactant gas within the reactor.

According to this type of epitaxial film deposition system, the reactor has an inner wall which is a cylindrical tube, and the wafer is mounted on the susceptor so that the planar direction of its surface on which the epitaxial film is to be formed is oriented approximately orthogonally to the inner wall of the reactor. The wafer is heated up by the first heating unit, and the reactant gas is supplied into the reactor from the supply orifice so as to circulate within the reactor along its inner wall direction, which is a direction approximately parallel to the epitaxiai film deposition surface of the wafer; and thereby an epitaxial film is formed on the wafer. The remainder of the reaction gas within the reactor is vented from the exhaust aperture.

By the reactant gas circulating in this predetermined direction within the reactor, the epitaxial film which is formed on the wafer has good film uniformity of film quality and film thickness and the like, while this epitaxial film deposition system does not require any wafer rotation mechanism. Accordingly, it becomes possible to perform formation of an epitaxial film on the wafer which is kept stationary, with the reactant gas being supplied so as to circulate over the surface of the wafer on which the epitaxial film is to be formed, in a direction which is approximately parallel to that surface.

Furthermore, in order to solve the above described problems, according to another aspect of the present invention, there is provided an epitaxial film deposition system which performs formation of an epitaxial film. The device includes: a tubular reactor; a susceptor, provided within the reactor, and on which a wafer is mounted so that the planar direction of a surface thereof on which the epitaxial film is to be formed is oriented approximately parallel to the inner wall of the reactor; a heating unit which heats the wafer mounted on the susceptor; supply orifices which supply a reactant gas into the reactor from both ends thereof; and an exhaust aperture which vents the reactant gas within the reactor, provided in the tubular wall of the reactor.

According to this type of epitaxial film deposition system, the wafer is mounted on the susceptor so that the planar direction of its surface on which the epitaxial film is to be formed is oriented approximately orthogonally to the inner wall of the tubular reactor, and the wafer is heated up by the first heating unit. The reactant gas is supplied into this tubular reactor from both ends thereof at, for example, appropriate timings, and thereby an epitaxial film is formed on the wafer, with the remainder of the reaction gas within the reactor being vented from the exhaust aperture.

By supplying the reactant gas from both the ends of the tubular reactor (as opposed to flowing the reactant gas along one direction within the reactor), the epitaxial film which is formed on the wafer has good uniformity of film quality and film thickness and the like, while this epitaxial film deposition system does not require any wafer rotation mechanism. Accordingly, it becomes possible to perform formation of an epitaxial film on the wafer which is kept stationary, with the reactant gas being supplied alternately from mutually different directions over the surface of the wafer on which the epitaxial film is to be formed, the directions being approximately parallel to the surface of the wafer.

With the epitaxial film deposition system of the present invention, without providing any wafer rotation mechanism, it is possible to form an epitaxial film which is satisfactory from the point of view of uniformity of film quality, film thickness, impurity density and the like. Accordingly, it becomes possible to perform formation of an epitaxial film at a high temperature which is much elevated above 1500° C., and in addition to an Si epitaxial film, various types of epitaxial film such as an SiC epitaxial film can be formed under various process conditions.

As a result, it becomes possible to manufacture, using SiC, a semiconductor device of high product quality, and moreover, of high performance, at a good yield rate.

### BRIEF DESCRIPTION OF THE DRAWINGS

FIG. 1 is a schematic cross-sectional view showing the main portions of an epitaxial film deposition system according to a first embodiment of the present invention;

FIG. 2 is an enlarged view of a portion A of FIG. 1;

FIG. 3 is a schematic cross-sectional view of the epitaxial film deposition system according to the first embodiment, taken looking in a direction shown by the arrows 3-3 in FIG. 1;

FIG. 4 is a schematic plan view of the main portions of the epitaxial film deposition system according to the first embodiment;

FIG. 5 is a schematic cross-sectional view showing the main portions of an epitaxial film deposition system according to a second embodiment of the present invention;

FIG. 6 is a schematic cross-sectional view of the epitaxial film deposition system according to the second embodiment, taken looking in a direction shown by the arrows 6-6 in FIG. 5;

FIG. 7 is a schematic cross-sectional view showing the main portions of an epitaxial film deposition system according to a third embodiment of the present invention;

FIG. 8 is a first partial view showing a relationship between the amount of a reactant gas supplied, and the time during which the reactant gas is supplied; and

FIG. 9 is a second partial view showing the relationship between the amount of the reactant gas supplied, and the time during which the reactant gas is supplied.

### DETAILED DESCRIPTION OF THE PREFERRED EMBODIMENTS

In the following, taking as an example the case of formation of an SiC epitaxial film, embodiments of the present invention will be explained in detail with reference to the drawings.

First, a first embodiment of the invention will be explained.

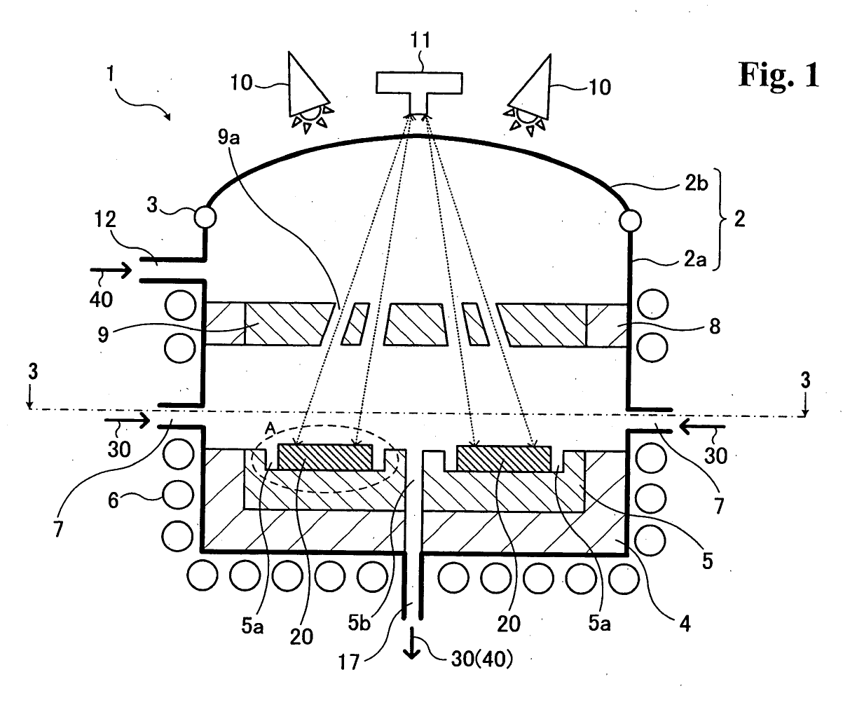

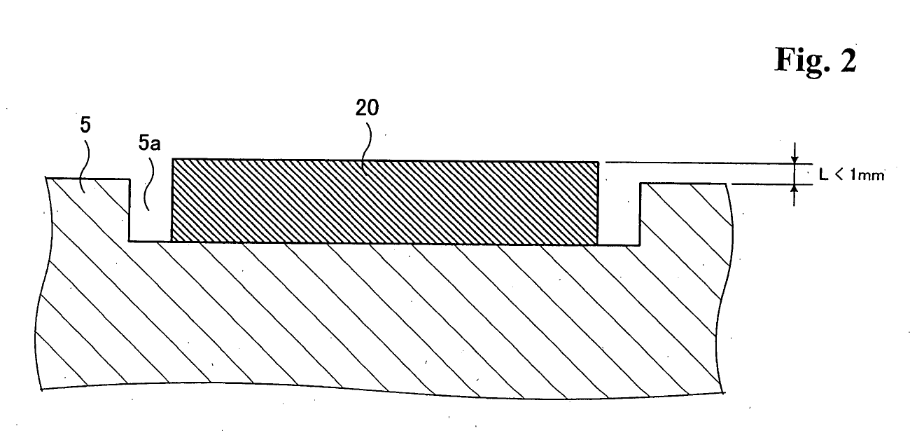

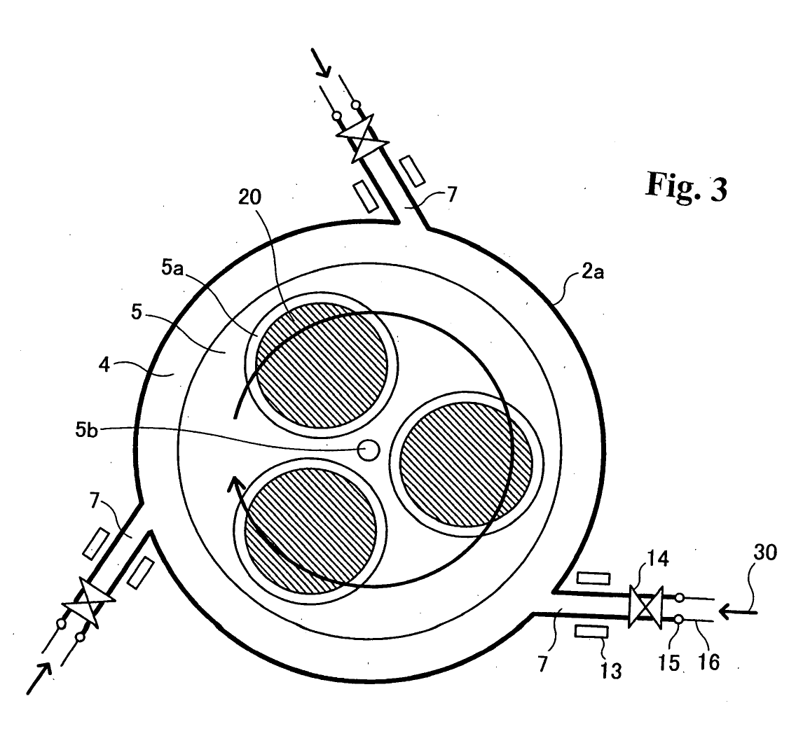

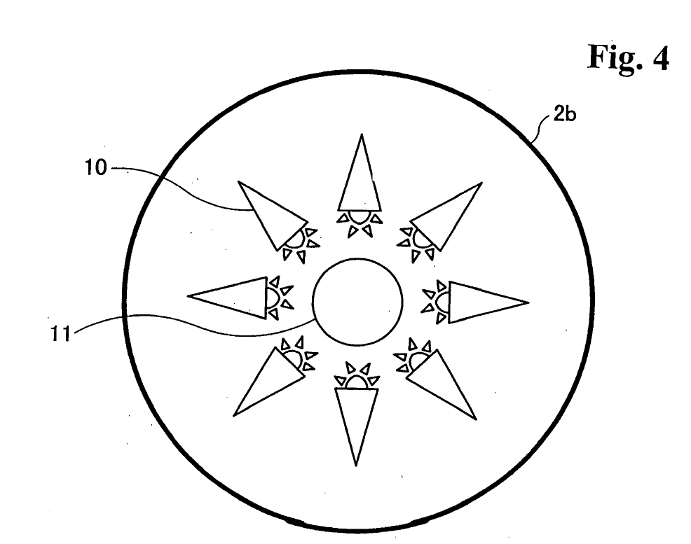

FIG. 1 is a schematic cross-sectional view showing the main portions of an epitaxial film deposition system according to the first embodiment; FIG. 2 is an enlarged view of a portion A of FIG. 1; FIG. 3 is a schematic cross-sectional view of this epitaxial film deposition system according to the first embodiment taken looking in a direction shown by the arrows 3-3 in FIG. 1; and FIG. 4 is a schematic plan view of the main portions of the epitaxial film deposition system according to the first embodiment. The epitaxial film deposition system 1 shown in FIG. 1 comprises a reactor 2 which comprises a reaction vessel 2a made from quartz glass and a lid 2b also made from quartz glass; the lid 2b is fitted on the reaction vessel 2a via an O-ring 3, so that the interior of the reactor 2 is tightly sealed. In its overall shape, this reactor 2 is made with its side portion shaped as a cylindrical tubular interior wall, and with its upper portion being rounded so as to be approximately dome shaped. By making the reactor 2 in this manner, i.e. not as a circular cylinder but instead dome shaped, it is ensured that the reactor 2 is not crushed by atmospheric pressure, even when forming an SiC epitaxial film in low ambient pressure conditions.

At the bottom portion within the reaction vesse 12a, a susceptor 5 made, for example, from graphite or the like is provided on an insulation 4, and SiC wafers 20 on which SiC epitaxial films are to be formed are mounted on this susceptor 5. These SiC wafers are mounted on the susceptor 5 so that the directions of planar surfaces thereof on which the SiC epitaxial films are to be formed are oriented in a direction which is almost orthogonal to the inner wall of the reaction vessel 2a.

The susceptor 5 has been processed by being countersunk, so that, as shown in FIGS. 1 and 2, on it there are formed countersunk portions 5a whose diameters are, for example, some millimeters greater than the diameter of the SiC wafers 20. The SiC wafers 20 are mounted in these counter sunk portions 5a. It should be understood that this epitaxial film deposition system 1 is built for performing batch processing at one time of a plurality of these SiC wafers 20, three in this example, as shown in FIG. 3.

When making the susceptor 5, the surface heights of the SiC wafers 20 and the surface height of the susceptor 5 are arranged so as to define a step L, as shown in FIG. 2, of 1 mm or less, and desirably of 300 μm or less. This is in order to ensure that although, as will be described hereinafter, a reactant gas 30 is directed to flow in a layer across the surface region of the SiC wafer 20 in a direction almost parallel to the surface on which the SiC epitaxial film is to be formed, no turbulence is caused in this laminar flow due to the step between the SiC wafers 20 and the susceptor 5.

Furthermore, around the periphery of the bottom portion of the reaction vessel 2a, there is provided a high frequency coil 6 for heating up a reactant gas 30 which is supplied to within the reactor 2 and the SiC wafers 20. This epitaxial film deposition system 1 is made so as, by controlling the output of this high frequency coil 6 and the output of halogen lamps 10 and so on which will be described hereinafter, to be able to heat up the SiC wafers 20 to around 1500° C. to around 2200° C.

Supply orifices 7 are provided at a plurality of spots within the reaction vessel 2a, in this embodiment, at three spots which are mutually spaced apart by angles of 120°, as shown in FIG. 3 so that a reactant gas 30 may be supplied in predetermined almost horizontal directions, and thereby it is arranged to perform supply of the reactant gas 30 into the reactor 2 from three directions. The arrow sign in the clockwise rotational direction in FIG. 3 shows the flow direction of the reactant gas 30. In this manner, with this epitaxial film deposition system 1, by providing the supply orifices 7 so that the reactant gas 30 which is supplied from them flows along the direction of the inner wall of the reaction vessel 2a, and by setting the flow rate and so on thereof in an appropriate manner, it is arranged for the reactant gas 30 to flow in a circular manner as a layer over the surface regions of the SiC wafers 20 within the reactor 2. And the reactant gas 30 which has been supplied in this manner is used, while it thus circulates within the reactor 2, in an epitaxial film deposition reaction at the surfaces of the SiC wafers 20. By doing this, it is arranged not to require any mechanical mechanism for causing the SiC wafers 20 to be rotated, while still being able to form an SiC epitaxial film of good uniformity on the SiC wafers 20.

Furthermore, an insulation 8 and a graphite plate 9 at the interior thereof are provided within the reaction vessel 2a in parallel with the susceptor 5, at a position which is separated from the susceptor 5 by a few centimeters to a few tens of centimeters, on the upper side of the supply orifices 7 (on the side of the lid 2b). By setting up the graphite plate 9 in this manner, the reactant gas 30 which is supplied from the supply orifices 7 so as to circulate within the reactor 2 is to a large extent detained at the surface regions of the SiC wafers 20, and furthermore the flow of the reactant gas 30 which circulates within the reactor 2 does not become very turbulent on the side of the lid 2b.

The graphite plate 9 is arranged to be heated up by the high frequency coil 6 which is provided on the outside of the reaction vessel 2a, and by halogen lamps 10 which are provided on the outside of the lid 2b. Furthermore, at the central portion of the exterior side of the lid 2b, there is provided a pyrometer 11 for monitoring the surface temperature of the SiC wafers 20. The halogen lamps 10 for heating up the graphite plate 9 are provided as a plurality arranged in a circle with the pyrometer 11 at the center thereof, as shown in FIG. 4: in this case, eight halogen lamps 10 are thus provided.

When forming the SiC epitaxial film, in order to maintain the uniformity of the temperature distribution within the surface of each of the SiC wafers 20, and also the uniformity of the temperature distribution between different ones of the SiC wafers 20, it is arranged for the surface temperatures of a plurality of spots to be detected by the pyrometer 11. Due to this, in order to ensure the lines of sight for the pyrometer 11 (the dotted lines in FIG. 1), there are provided the same number of minute holes 9a in the graphite plate 9 within the reactor 2, as the number of spots at which the surface temperature of the SiC wafers 20 is to be monitored.

Thus, if the reactant gas 30 which is supplied to the region on the side of the SiC wafers 20, i.e. lower than the graphite plate 9, passes through these minute holes 9a, and flows to the side of the lid 2b, i.e. higher than the graphite plate 9, and polycrystalline SiC adheres to its inner wall or the like, then the detection of temperature by the pyrometer 11 becomes inaccurate, and furthermore the beneficial heating effect by the halogen lamps 10 is lost.

In order to prevent this, in this epitaxial film deposition system 1, a supply orifice 12 is provided at a position in the reaction vessel 2a which is higher than the graphite plate 9, in order to supply a minute amount of inactive gas 40 (so called “gas for pressure adjustment”) such as hydrogen (H₂) or argon (Ar) or the like. By supplying this gas for pressure adjustment 40 from the supply orifice 12, a minute pressure difference of for example some Torr (1 Torr=133.32 Pa) is created between the regions above and below the graphite plate 9, and it is arranged for this gas for pressure adjustment 40 to flow from above to below, so that the reactant gas 30 is prevented from flowing from below to above.

At this time, the flow rate of the gas for pressure adjustment 40 is made to be a minute amount on the order of a few sccm to a few hundreds of sccm (1 sccm=1 mL/min, at 0° C. and 101.3 kPa), so as not to disturb the laminar flow of the reactant gas 30 at the surface regions of the susceptor 5 and the SiC wafers 20. However, the most appropriate value of the flow rate of this gas for pressure adjustment 40 fluctuates according to the capacity of the reactor 2.

It should be understood that, although generally nitrogen (N₂) is used as an inactive gas, it is not possible to utilize it here as the gas 40 for pressure adjustment, since N₂ gas acts as an n type dopant when forming such an SiC epitaxial film, as described hereinafter.

The pyrometer 11 detects the surface temperatures of the SiC wafers 20 at a plurality of points through the minutes holes 9a in the graphite plate 9, and the epitaxial film deposition system 1 performs feedback control by PID control or the like of the outputs of the high frequency coil 6 and the halogen lamps 10, so as to make uniform the distribution of temperature within each of the single SiC wafers 20, and also the distribution of temperature between the different SiC wafers 20. It is arranged for the overall temperature of the SiC wafers 20 to be controlled by the output of the high frequency coil 6, and for their local temperatures to be principally controlled by the output of the halogen lamps 10.

At this time, the output of each of the halogen lamps 10 is controlled so that, when the temperature in a specified region of the SiC wafer 20 has become lower than a predetermined value, the graphite plate 9 directly over this-specified region is locally heated up, and thereby the specified region of the SiC wafer 20 is heated up by radiant heating from the graphite plate 9. With this type of epitaxial film deposition system 1, by feedback controlling the output of each of the halogen lamps 10, via the graphite plate 9, it is arranged to keep uniform the temperature distribution within each one of the SiC wafers 20, and also the temperature distribution between different ones of the SiC wafers 20.

There may be used, for example: as the reactant gas which is supplied from the supply orifices 7 into the reactor 2, a gas which includes H₂ as a carrier gas; as a source gas, monosilane (SiH₄) or propane (C₃H₈) or the like; and, as a dopant, in the case of n-type N₂, and in the case of p-type trimethyl-aluminum (TMA). The reactant gas 30 which has been supplied into the reactor 2 in three directions from the supply orifices 7 circulates in the region between the susceptor 5, and the graphite plate 9, which have been heated up, in a laminar flow over the surface regions of the SiC wafers 20, and, until it is exhausted, an epitaxial film deposition reaction takes place at the surfaces of the SiC wafers 20.

Making the reactant gas 30 flow as a layer at the surface regions of the SiC wafers 20 is performed in order to ensure the film quality of the SiC epitaxial film which is formed, and good uniformity of its film thickness and its impurity density and so on. For this, in this epitaxial film deposition system 1, the number of the supply orifices 7 and their arrangement, the flow rate of the reactant gas 30 from these supply orifices 7, the arrangement of an exhaust aperture 17 which will be described hereinafter, and the like, are set appropriately.

Furthermore, as shown in FIG. 3, a heater for preliminary heating 13 is provided to this epitaxial film deposition system 1, in order to pre-heat the reactant gas 30 in the supply orifices 7 before it is supplied to the reactor 2. By providing this type of heater for preliminary heating 13, it becomes possible to suppress cooling due to the reactant gas 30 which is newly supplied to the susceptor 5, the SiC wafers 20, and the graphite plate 9, and consequent loss of the uniformity of the temperature distributions in those elements, to the minimum possible level. Furthermore, injection valves 14 are provided to the supply orifices 7, and their ends are connected via O-rings 15 to stainless steel conduits 16, which are supply lines for the reactant gas 30. In the same way as for the supply orifices 7 for the reactant gas 30, a heater for preliminary heating and an injection valve are provided to the supply orifice 12 for the gas for pressure adjustment 40 as well, and the end thereof is connected to a supply line for the gas for pressure adjustment 40 via an O-ring.

It should be understood that this preliminary heating of the reactant gas 30 may be adjusted within the range of around 200° C. to around 300° C., and, in the present state of affairs, it is desirable for it to be performed at a temperature which does not exceed 300° C. The first reason for this is that the autolysis of SiH₄ commences from around 250° C. (refer to an MSDS data sheet). Although, due to the difficulty of handling SiH₄, there are many points regarding its chemical constitution and its reactivity which are not accurately understood, it is considered that its autolysis reaction starts progressively from 250° C., and progresses gently up to 300° C. However it is anticipated that, at a temperature of greater than 300° C., the autolysis of SiH₄ will become severe, and in this case it becomes extremely difficult to handle. Furthermore, the second reason is that, at the present time, the allowable temperature limit of the O-rings 15 is somewhat higher than 300° C.

However, it is also possible to enhance the preliminary heating temperature by replacing the reactant gas 30 with a gas which is difficult to autolyze, such as disilane (SiH₆), monochlorosilane (SiH₃Cl), dichlorosilane (SiH₂Cl₂), trichlorosilane (SiHCl₃), tetrachlorosilane (SiCl₄) or the like. Furthermore, it is also possible to enhance the preliminary heating temperature by, instead of the O-rings 15, providing an element for maintaining gas-tightness, such as a gasket or the like, whose heat resistance is excellent.

The reactant gas 30 in the region below the graphite plate 9 and the minute amount of the gas for pressure adjustment 40 included therein are exhausted, as shown in FIGS. 1 and 3, from an exhaust aperture 17 via a through hole 5b which is provided in the central portions of the insulation 4 and the susceptor 5. This exhaust aperture 17 is connected to a stainless steel conduit through a flow adjustment valve and via an O-ring, and is further connected, downstream thereof, to a dry pump or a turbo pump for pressure reduction. Furthermore it is possible to exhaust the gas from the interior of the reactor 2 from this exhaust aperture 17, before supplying the reactant gas 30.

When forming an SiC epitaxial film with an epitaxial film deposition system 1 which has this type of structure, first, the SiC wafers 20 are mounted on the susceptor 5 and the pressure within the reactor 2 is reduced, and then the SiC wafers 20 are heated up by the high frequency coil 6 and the halogen lamps 10 while their temperatures are detected with the pyrometer 11. And, while further performing temperature control of the SiC wafers 20, along with supplying the pre-heated reactant gas 30 from the supply orifices 7 to the interior of the reactor 2 in predetermined flow rates and in predetermined directions, the pre-heated gas for pressure adjustment 40 is supplied from the supply orifice 12 to the interior of the reactor 2 in a predetermined flow rate.

The reactant gas 30 which is supplied from the supply orifices 7 is heated up within the reactor 2, and circulates therein while flowing in a layer over the surface regions of the SiC wafers 20. And, at this time, the reactant gas 30 is used in an epitaxial film deposition reaction, with the remainder thereof being exhausted to the exterior of the reactor 2 from the exhaust aperture 17. Incidentally, the removal and replacement of the SiC wafers 20 before and after formation of an SiC epitaxial film thereon may be performed, after having opened the lid 2b, by using clean tweezers or the like made from Teflon (registered trademark), or by using a non-contact type conveyance device of the Bernoulli chuck type.

The formation of this type of SiC epitaxial film may be performed under, for example, the following kind of process conditions:

Pressure: 20 Torr to 70 Torr

Carrier H₂ flow rate: 5 slm to 40 slm (1 slm=1 L/min, 0° C., 101.3 kPa); SiH₄ flow rate: 0.4 sccm to 20 sccm

C₃H₈ flow rate: 0.2 sccm to 10 sccm

N₂ flow rate: 0.04 sccm to 2 sccm

TMA flow rate: 0.0006 sccm to 0.03 sccm

Wafer temperature: 1500° C. to 2200° C.

However, with regard to the flow rate of the gas which constitutes the reactant gas 30, the total of the amounts which are supplied from the three supply orifices 7 at three positions is shown. Furthermore, the flow rate of the gas is the actual flow rate with the carrier H₂ excluded, and in practice it is supplied diluted to around 10% with an H₂ base. Accordingly, the actual flow rate of H₂ may be obtained by adding the flow rate of the dilution H₂ to the flow rate of the carrier H₂.

As has been explained above, with this epitaxial film deposition system 1 according the first embodiment of the present invention, it is possible to form an SiC epitaxial film which has good film quality and uniformity of film thickness and impurity density and so on, without using any mechanical wafer rotation mechanism. Furthermore, since no wafer rotation mechanism is provided, it is possible to form the SiC epitaxial film at a temperature which is much increased above 1500° C. to 1600° C. Yet further since, along with heating up the SiC wafers 20 with the high frequency coil 6, it is also arranged to further heat them up locally via the graphite plate 9 with the halogen lamps 10, accordingly it is possible appropriately to control the temperature within the surface of each of the SiC wafers 20, and the temperature between different ones of the SiC wafers 20. Due to this, under various process conditions, it becomes possible to form a desired SiC epitaxial film which has excellent film quality and uniformity of film thickness and impurity density and soon, in a stable manner.

Moreover, since this epitaxial film deposition system 1 is of the batch type, it is possible to form a desired SiC epitaxial film on each of a plurality of SiC wafers 20 with high efficiency.

Furthermore, with this epitaxial film deposition system 1, it is possible to extend the length of the maintenance cycle, since no wafer rotation mechanism is provided, and also, due to the employment of the gas for pressure adjustment 40 and so on, unnecessary deposition of SiC to the inner wall of the reactor 2 is suppressed.

It should be understood that although, in the above explanation, the example was explained as being an epitaxial film deposition system 1 which batch processes three SiC wafers 20 at one time, the present invention is not to be considered as being limited to this case where the number of wafers processed at one time is three. By increasing the diameter of the susceptor 5 and so on, it would also be possible to set up four or more wafers on it. It would also be acceptable to change the shape of the susceptor 5(the dimensions and number of the countersinks 5a and so on), according to the diameters of the SiC wafers 20, and according to how many are to be processed in one batch.

Yet further, although in the above described first preferred embodiment, the reactant gas 30 was supplied into the interior of the reactor 2 from three directions by the supply orifices 7 which were provided at three spots on the reactor 2, it would also be acceptable to arrange to supply the reactant gas 30 from more than three directions, by providing supply orifices 7 in more than three spots.

Furthermore, although here eight halogen lamps 10 were provided arranged in a ring around the pyrometer 11 as a center, the number thereof may be increased or decreased according to requirements. Moreover, the halogen lamps 10 may be arranged in concentric circles with the pyrometer 11 as a center. For example, it would also be possible to provide twelve halogen lamps 10, with four of them being arranged around an inner circle, and the other eight of them being arranged around an outer circle. Yet further, although such halogen lamps 10 provide a high output at a comparatively low price, it would also be acceptable to use radiant type heaters, rather than the halogen lamps 10.

Next, a second embodiment of the present invention will be explained.

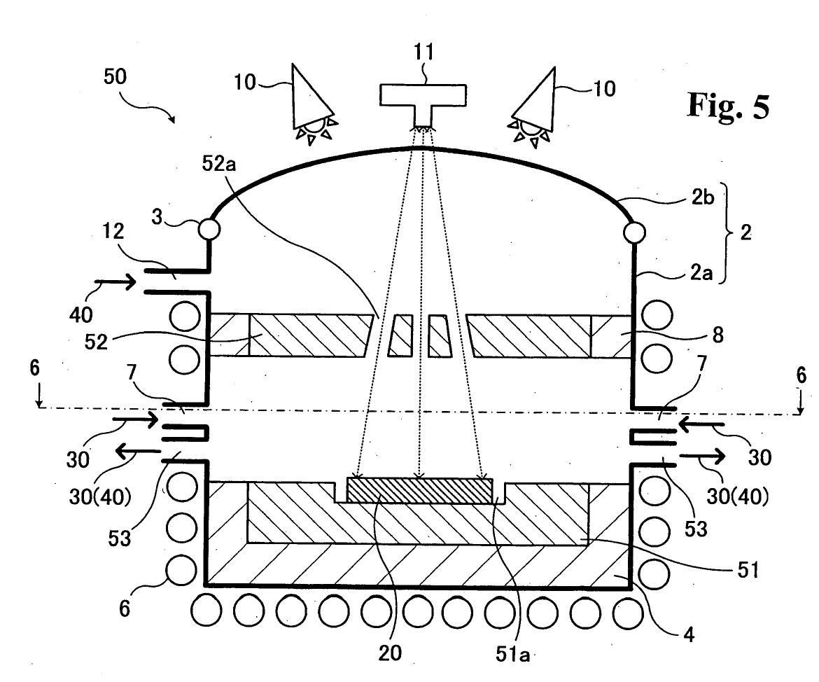

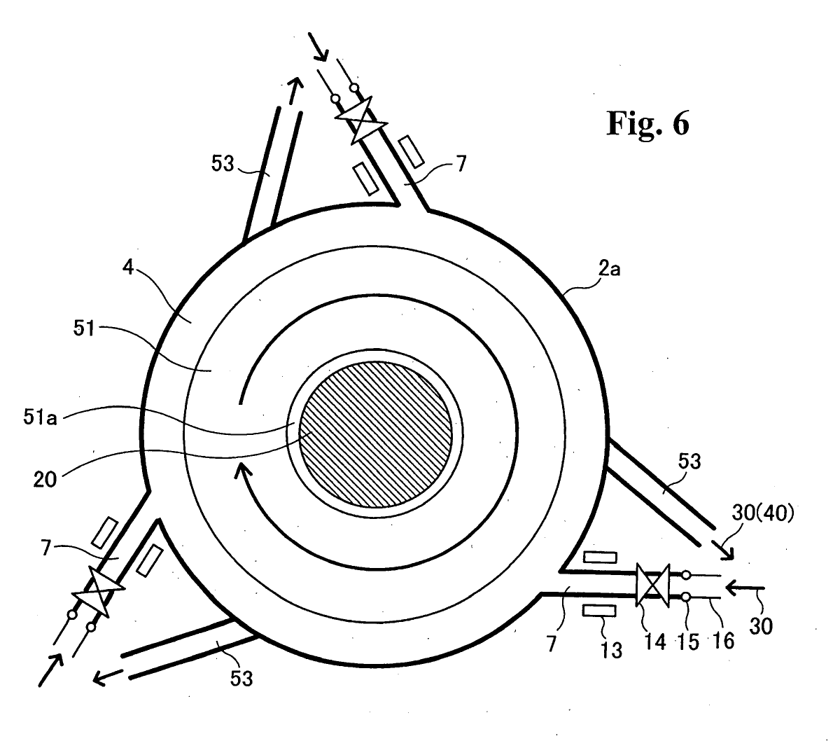

FIG. 5 is a schematic cross-sectional figure showing the main portions of an epitaxial film deposition system according to the second embodiment of the present invention, and FIG. 6 is a schematic cross-sectional figure of this epitaxial film deposition system according to the second embodiment, taken looking in a direction shown by the arrows 6-6 in FIG. 5. In FIGS. 5 and 6, to structural elements which are the same as ones appearing in FIGS. 1 and 3, the same reference symbols will be appended, and the explanation thereof will be omitted.

The epitaxial film deposition system 50 shown in FIGS. 5 and 6 differs from the epitaxial film deposition system 1 of the first preferred embodiment described above which was made so as to perform batch processing on a plurality of the SiC wafers 20, by the feature that the epitaxial film deposition system 50 performs processing of one SiC wafer 20 at a time.

With this epitaxial film deposition system 50 of the second embodiment, since it performs single wafer type processing, a susceptor 51 is used which is formed with a countersink 51a at its central portion, and a single SiC wafer 20 is mounted therein. Just as in the first embodiment described above, the step between the susceptor 51 and the SiC wafer 20 is kept within a predetermined range, so that no turbulence should occur in the flow of the reactant gas 30 which is circulating in a layer over the surface region of the SiC wafer 20. A plurality of minute holes 52a for detection by a pyrometer 11 of the temperature of the single SiC wafer 20 which is mounted on the susceptor 51 are provided in a graphite plate 52 which is mounted to face the susceptor 51. It should be understood that the temperature control of the SiC wafer 20 is performed using the pyrometer 11, a high frequency coil 6, and halogen lamps 10, by the same method as in the above described first embodiment.

Furthermore, since in the case of this single wafer processing type of epitaxial film deposition system 50, the SiC wafer 20 is disposed in the-central portion of the susceptor 51. Accordingly, exhaust apertures 53 for the reactant gas 30 supplied to the interior of the reactor 2, which now also includes a minute amount of the gas for pressure adjustment 40, are provided at a plurality of spots on the reactor wall. This configuration is different from the case with the batch processing type epitaxial film deposition system 1 of the above described first embodiment, in which the through hole 5b connected to the exhaust aperture 17 was provided in the central portion of the susceptor 5.

If the exhaust apertures 53 are provided in the wall of the reactor 2 in this manner, it is desirable for them to be provided in the vicinity of each of the supply orifices 7 in such an orientation that, as shown in FIG. 6, the flow of the reactant gas 30 which circulates in a laminar flow within the reactor 2 is vented in a smooth manner without the occurrence of turbulence. As will be easily understood from FIGS. 5 and 6, the structure of the supply orifices 7 and the exhaust apertures 53 is, in this second embodiment, arranged so that their heights as seen from the direction of the SiC wafer 20 vary. There is no problem even if the heights of the supply orifices 7 and the exhaust apertures 53 varies in this manner, as long as no turbulence is generated in the flow of the reactant gas 30. More desirably, the heights of the supply orifices 7 and of the exhaust apertures 53 may be set to be coplanar as seen from the direction of the SiC wafer 20.

With an epitaxial film deposition system 50 of this type of structure as well, it is possible to form an SiC epitaxial film at high temperature without using any mechanical wafer rotation mechanism, and moreover, by appropriate temperature control, it is possible to form the SiC epitaxial film in a stable manner with excellent film quality and film thickness and the like. Furthermore, since with this single wafer processing type epitaxial film deposition system 50, the diameter of the susceptor 51 can be made smaller as compared with a batch type epitaxial film deposition system, accordingly it becomes possible to reduce the overall dimensions of the device.

It should be understood that although, in the above explanation, three of the exhaust apertures 53 were provided at three spots within the reactor 2, corresponding to the three spots at which the three supply orifices 7 were provided, it would also be acceptable to arrange to provide both the supply orifices 7 and the exhaust apertures 53 at more than three spots, so as to perform supply and venting of the reactant gas 30. Furthermore, just as in the case of the above described first embodiment, it would also be acceptable suitably to change the number and the arrangement and so on of the halogen lamps 10 or other heaters.

Next, a third embodiment of the present invention will be explained.

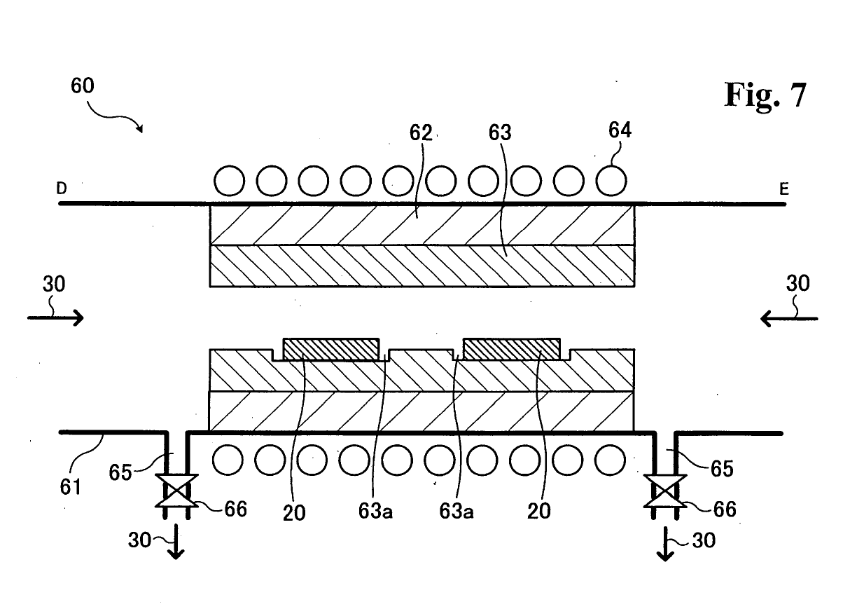

FIG. 7 is a schematic cross-sectional figure showing the main portions of an epitaxial film deposition system according to this third embodiment of the present invention. To structural elements which are the same as ones appearing in FIG. 1, the same reference symbols will be appended, and the explanation thereof will be omitted.

The epitaxial film deposition system 60 shown in FIG. 7 comprises a reactor 61 which is made from quartz, and an insulation 62 is disposed circumferentially around a predetermined region of its interior wall, with a susceptor 63 being further disposed circumferentially -on the inside of this insulation 62. Two countersinks 63a are formed in a portion of the susceptor 63, and it is arranged to mount one SiC wafer 20 in each of these. It should be understood that the step between the susceptor 63 and the SiC wafers 20 are kept within a predetermined range, so as not to cause any turbulence in the flow of the reactant gas 30 which is flowing within this reactor 61. Furthermore, on the outer circumference of the reactor 61, there is arranged a high frequency coil 64 for heating up the SiC wafers 20 and the reactant gas 30 after it has been supplied. It is arranged to be able to heat up the SiC wafers 20 with this high frequency coil 64 to approximately 1500° C. to approximately 2200° C.

Supply lines for the reactant gas 30 are connected to both ends of this reactor 61, and these constitute supply orifices which supply the reactant gas 30 to the SiC wafers 20, via injection valves and preliminary heating regions. Furthermore, two exhaust apertures 65 are provided to the reactor 61 at two spots outside the region in which the insulation 62 and the susceptor 63 are disposed, so that the reactant gas 30, which is supplied into the reactor 61 from both its two ends, is then vented from the exhaust apertures 65.

In this manner, with this epitaxial film deposition system 60, it is arranged for it to be possible to supply the reactant gas 30 from both of the ends of the tubular reactor 61. In other words, supply of the reactant gas 30 is performed both from its one end D and from its other end E. When actually performing film formation, the supply of the reactant gas 30 from the D end and the supply of the reactant gas 30 from the E end are both performed at individually appropriate timings.

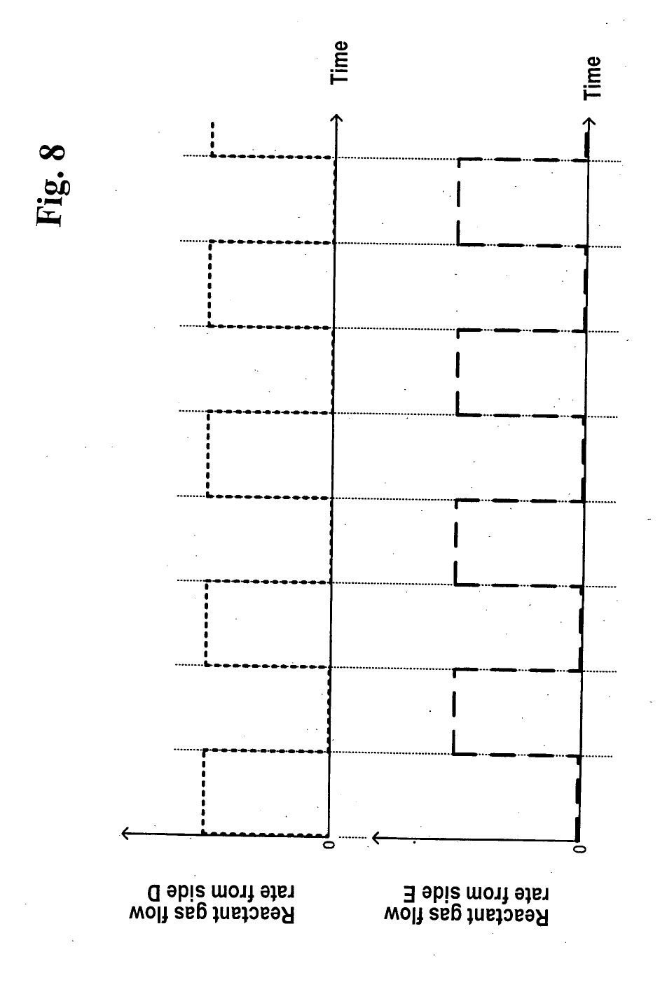

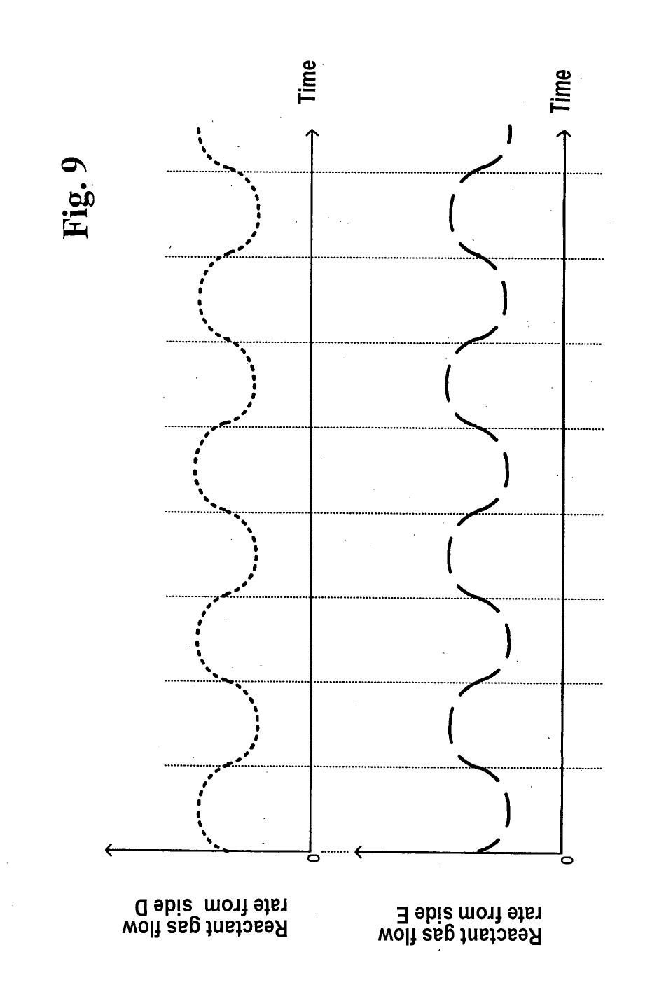

FIGS. 8 and 9 are figures showing the relationship between the amount of the reactant gas supplied, and the time at which it is supplied. It should be understood that, in FIG. 8 and FIG. 9, the dotted line shows the relationship between the supply amount of the reactant gas 30 from the D end and the time at which it is supplied, while the broken line shows the relationship between the supply amount of the reactant gas 30 from the E end and the time at which it is supplied.

In this epitaxial film deposition system 60, the reactant gas 30 is supplied in rectangular pulses from both the D end and the E end, as shown in FIG. 8, and moreover these supplies of the reactant gas 30 to the surface region of the SiC wafer 20 are not mutually overlapped, and also the supply of gas is not interrupted at any time. And, with regard to venting of the reactant gas 30 which has been supplied, for example, a certain time lag is interposed equal to the time from after the reactant gas 30 which is supplied from both the D end and the E end passes over the surface regions of the SiC wafers 20 until it arrives at the exhaust apertures 65, and this is performed at the timing of the supplies of the reactant gas 30 from the ends D and E and at the timing of the phases thereof. The exhaust aperture 65 which is used for the venting corresponds to which of the ends D and E the reactant gas 30 has been supplied from, and is controlled by opening and closing the valves 66. For example, when the reactant gas 30 has been supplied from the D end, its venting is performed from only the exhaust aperture 65 on the E end, which is on the opposite side of the SiC wafers 20; while, when the reactant gas 30 has been supplied from the E end, its venting is performed from only the exhaust aperture 65 on the D end, which again is on the opposite side of the SiC wafers 20.

It should be understood that although here it has been arranged to supply the reactant gas 30 in rectangular pulses, it would also be possible, in the same manner, to supply the reactant gas 30 from the ends D and E in the form of a sinusoidal pattern.

Furthermore, as shown in FIG. 9, it would also be possible to supply the reactant gas 30 in sinusoidal wave patterns. In this case, the phases of the supply waveforms of the reactant gas 30 from the ends D and E would be mutually shifted a part by ½ wavelength, so that the supply from the end E was interrupted during the supply from the end D, and, conversely, the supply from the end D was interrupted during the supply from the end E. The venting is performed, for example, with a time lag equal to the amount of time from when the reactant gas 30 supplied in a large amount from the ends D and E with the respective supply waveforms passes over the surface regions of the SiC wafers 20 until it arrives at the exhaust apertures 65.

In this manner, according to the epitaxial film deposition system 60 of this third embodiment, by using this tubular reactor 61, it becomes possible to form an SiC epitaxial film at a high temperature with a simple device, and furthermore it becomes possible to form an SiC epitaxial film having excellent film quality and film thickness and the like.

It should be understood that although, in the above explanation, the case of the formation of an SiC epitaxial film has been described by way of example, of course the epitaxial film deposition systems 1, 50, and 60 of the above described first through third embodiments of the present invention may be applied to the formation of various other types of epitaxial film for semiconductors, such as an Si epitaxial film or the like.

The disclosure of Japanese Patent Application No. 2005-122107 filed on Apr. 20, 2005, is incorporated herein.

What is claimed is:

1. An epitaxial film deposition system for forming an epitaxial film, comprising:
a reactor comprising a circular inner wall;
a susceptor, provided within the reactor, for mounting thereon a wafer so that a planar direction of a wafer surface on which the epitaxial film is to be formed is oriented approximately orthogonally to the inner wall;
a first heating unit for heating the wafer mounted on the susceptor;
a first supply orifice for supplying a reactant gas into the reactor so as to circulate in a direction along the inner wall, the direction being approximately parallel to the wafer surface on which the epitaxial film is to be formed; and
an exhaust aperture for venting the reactant gas from within the reactor.

2. The epitaxial film deposition system of claim 1, further comprising a plate provided within the reactor so as to face a side of the susceptor on which the wafer is mounted,
wherein the first supply orifice supplies the reactant gas to a region in the reactor between the susceptor and the plate.

3. The epitaxial film deposition system of claim 2, further comprising a second heating unit for heating the plate,
wherein the first and second heating units have a controllable heat output so as to control a temperature of the wafer.

4. The epitaxial film deposition system-of claim 3, wherein the first and second heating units are capable of heating the wafer up to approximately 1500° C. to approximately 2200° C.

5. The epitaxial film deposition system of claim 2, further comprising
a temperature detection unit for detecting a temperature of the wafer, disposed exterior to the reactor and facing the plate, and
a hole provided in the plate to enable detection by the temperature detection unit of the wafer temperature.

6. The epitaxial film deposition system of claim 5, further comprising
a second supply orifice, provided in a region of the reactor on a top side of the plate, for supplying a pressure adjustment gas capable of preventing outflow of the reactant gas through the hole.

7. The epitaxial film deposition system of claim 1, wherein the susceptor has, at a central portion, a through hole for enabling communication between an interior of the reactor and the exhaust aperture, and the wafer is mounted around a periphery of the through hole.

8. An epitaxial film deposition system for forming an epitaxial film, comprising:
a tubular reactor comprising an inner wall, a first end, and a second end;
a susceptor, provided within the reactor, for mounting thereon a wafer so that a planar direction of a wafer surface on which the epitaxial film is to be formed is oriented approximately parallel to the reactor inner wall;
a heating unit for heating the wafer mounted on the susceptor;
supply orifices for supplying a reactant gas into the reactor from both of the first and second ends; and
an exhaust aperture, provided in the reactor inner wall, for venting the reactant gas from within the reactor.

9. The epitaxial film deposition system of claim 8, wherein the supply orifices are capable of delivering the reactant gas from the reactor first end and from the reactor second end at a different time.

10. The epitaxial film deposition system of claim 8, wherein a first exhaust aperture is provided at the reactor first end and a second exhaust aperture is provided at the reactor second end, with the wafer being mounted on the susceptor between the first exhaust aperture and the second exhaust-aperture, and wherein the second exhaust aperture vents the reactant gas supplied from the reactor first end, and the first exhaust aperture vents the reactant gas supplied from the reactor second end.

11. The epitaxial film deposition system of claim 8, wherein the heating unit is capable of heating the wafer up to approximately 1500° C. to approximately 2200° C.

12. A method of forming an epitaxial film on a wafer, comprising preparing an epitaxial film deposition system comprising a reactor having a circular inner wall; a susceptor for mounting thereon the wafer; a heating unit for heating the mounted-wafer; a supply orifice for supplying a reactant gas into the reactor; and an exhaust aperture for venting the reactant gas from within the reactor;
mounting the wafer in a stationary position on the susceptor so that a planar direction of a wafer surface on which the epitaxial film is to be formed is oriented approximately orthogonally to the inner wall; and
supplying the reactant gas into the reactor so as to circulate over the wafer surface and to circulate in a direction along the inner wall, the direction being approximately parallel to the wafer surface on which the epitaxial film is formed.

13. The method of forming an epitaxial film of claim 12, further comprising heating the wafer before supplying the reactant gas, and venting the reactant gas after circulation of the reactant gas in the reactor.

14. A method of forming an epitaxial film on a wafer, comprising
preparing an epitaxial film deposition system comprising a tubular reactor having an inner wall, a first end, and a second end; a susceptor capable of having mounted thereon the wafer; a heating unit for heating the mounted wafer; supply orifices for supplying a reactant gas into the reactor from both of a first end direction and a second end direction; and an exhaust aperture for venting the reactant gas from within the reactor;
mounting the wafer in a stationary position on the susceptor so that a planar direction of a wafer surface on which the epitaxial film is to be formed is oriented approximately parallel to the reactor inner wall;
supplying the reactant gas over the wafer surface in an alternating mode from the first end direction and the second end direction, the directions being approximately parallel to the wafer surface.

15. The method of forming an epitaxial film of claim 12, further comprising heating the wafer before supplying the reactant gas, and venting the reactant gas after circulation of the reactant gas in the reactor.
